(19) United States
(12) Patent Application Publication
(10) Pub. No.: US 2022/0045492 A1
(43) Pub. Date: Feb. 10, 2022

(54) WIRE HARNESS

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Takeshi SHIMIZU, Yokkaichi-shi (JP); Hirotaka BABA, Yokkaichi-shi (JP); Yuichi KIMOTO, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 17/275,227

(22) PCT Filed: Sep. 10, 2019
(86) PCT No.: PCT/JP2019/035469

§ 371 Date: Mar. 11, 2021

(30) Foreign Application Priority Data
Sep. 25, 2018 (JP) 2018-178535

(51) Int. Cl. H02G 3/04; H02G 3/30

(52) U.S. Cl. CPC H02G 3/0437; B60R 16/0215; H02G 3/0406; H02G 3/30

(57) ABSTRACT

A wire harness including: a plurality of wires each including a core wire, a tubular electromagnetic shield enclosing an outer circumference of the core wire, and an insulating sheath that includes a first covering that is filled between the core wire and the electromagnetic shield, that covers an outer circumferential surface of the core wire in intimate contact therewith, and that covers an inner circumferential surface of the electromagnetic shield in intimate contact therewith, and a second covering that covers an outer circumferential surface of the electromagnetic shield in intimate contact therewith; and a link that is formed as a single body with the second covering in each of the plurality of wires, and that is for linking adjacent wires of the plurality of wires into a single body; wherein the plurality of wires are configured to be dividable at the link.

### BACKGROUND

The present disclosure relates to a wire harness.

Conventionally, a wire harness used in a vehicle such as a hybrid vehicle or an electric vehicle is provided with wires for electrically connecting electrical devices such as a high-voltage battery and a high-voltage inverter (e.g., see JP 2016-54030A).

### SUMMARY

Incidentally, examples of electrical devices used in a vehicle such as a hybrid vehicle or an electric vehicle as described above include a high-voltage inverter and a high-voltage battery, and there are cases where a large current that is several hundreds of amperes in magnitude flows through a wire, for example. There is demand for improvement of the heat dissipation properties of a wire harness because, when a large current flows through a wire, the temperature of the wire is likely to increase due to an increase in the amount of heat generated by the wire.

An exemplary aspect of the disclosure provides a wire harness by which heat dissipation can be improved.

A wire harness according to an exemplary aspect includes a plurality of wires that each includes a core wire, a tubular electromagnetic shield enclosing an outer circumference of the core wire, and an insulating sheath that includes a first covering that is filled between the core wire and the electromagnetic shield, that covers an outer circumferential surface of the core wire in intimate contact therewith, and that covers an inner circumferential surface of the electromagnetic shield in intimate contact therewith, and a second covering that covers an outer circumferential surface of the electromagnetic shield in intimate contact therewith; and a link that is formed as a single body with the second covering in each of the plurality of wires, and that is for linking adjacent wires of the plurality of wires into a single body, in which the plurality of wires are configured to be dividable at the link.

According to the wire harness of the present disclosure, it is possible to improve heat dissipation.

### BRIEF DESCRIPTION OF THE DRAWINGS

FIG. 1 is a schematic configuration diagram showing a wire harness of one embodiment.

FIG. 2(a) is a transverse cross-sectional view showing a wire harness of one embodiment (a cross-sectional view along line 2a-2a in FIG. 3), and FIG. 2(b) is a transverse cross-sectional view showing a wire harness of one embodiment (a cross-sectional view along line 2b-2b in FIG. 3).

FIG. 3 is a schematic configuration diagram showing a wire harness of one embodiment.

FIG. 4 is a transverse cross-sectional view showing a wire harness of one embodiment (a cross-sectional view 4-4 in FIG. 3).

FIG. 5 is a schematic cross-sectional view showing a wire harness of one embodiment.

FIG. 6 is a transverse cross-sectional view showing a wire harness of a modification.

FIG. 7 is a transverse cross-sectional view showing a wire harness of a modification.

FIG. 8 is a schematic plan view showing a wire harness of a modification.

FIG. 9 is a transverse cross-sectional view showing a wire harness of a modification.

### DETAILED DESCRIPTION OF EMBODIMENTS

The following describes one embodiment of a wire harness with reference to the attached drawings. Note that, in the drawings, some of the components may be exaggerated or simplified for the sake of description. Also, the dimensional ratio of some parts may differ from their actual ratio. Also, to facilitate understanding of the description, some members are illustrated with a satin pattern, instead of being hatched in the cross-sectional views.

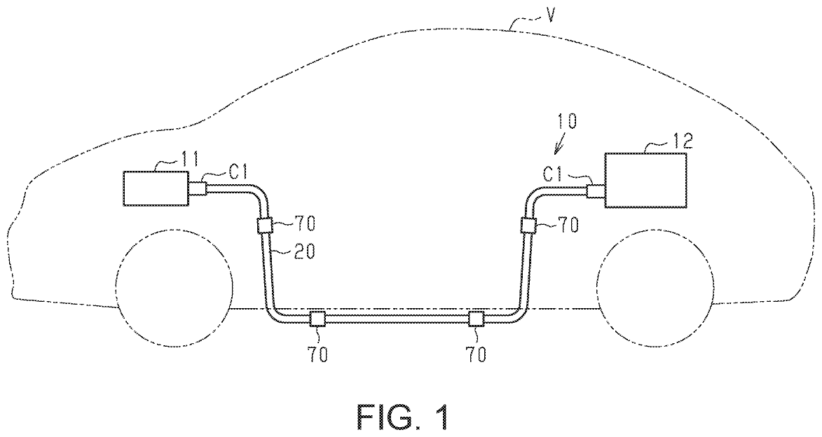

A wire harness 10 shown in FIG. 1 electrically connects two electric apparatuses (devices), or three or more electric apparatuses (devices). The wire harness 10 electrically connects an inverter 11 disposed in a front part of a vehicle V, such as a hybrid vehicle or an electric vehicle, and a high-voltage battery 12 disposed in a part of the vehicle V rearward of the inverter 11, for example. The wire harness 10 is routed under the floor of the vehicle, for example. The inverter 11 is connected to a wheel driving motor (not shown), which is a power source for driving the vehicle. The inverter 11 generates AC power from DC power that is supplied from the high-voltage battery 12, and supplies the AC power to the motor. The high-voltage battery 12 is a battery that can supply a voltage of several hundred volts, for example.

The wire harness 10 includes a plurality of wires 20, a pair of connectors C1 attached to opposite ends of the plurality of wires 20, and clamps 70 for fixing the plurality of wires 20 to the vehicle body of the vehicle V. The wires 20 are bendable two-dimensionally or three-dimensionally, for example. The wires 20 are bent into a predetermined shape according to the route where the wire harness 10 is to be routed, for example.

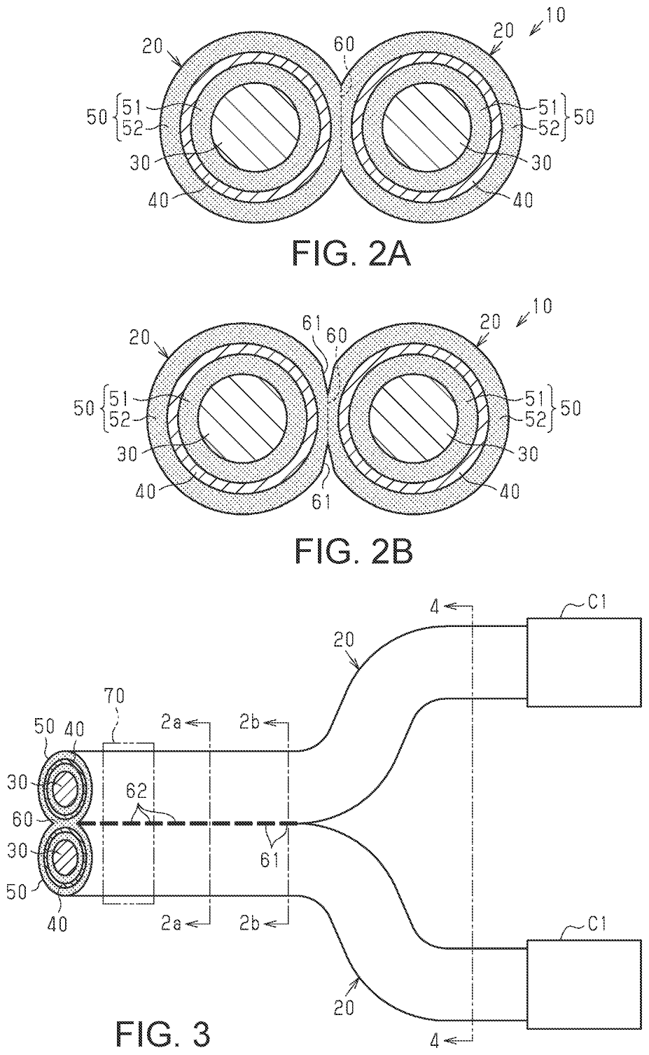

As shown in FIG. 2(a), the wires 20 each include a core wire 30, a tubular electromagnetic shielding member 40 (tubular electromagnetic shield) enclosing the outer circumference of the core wire 30, and an insulating sheath 50 in which the core wire 30 and the electromagnetic shielding member 40 are collectively embedded. The plurality of wires 20 have a linking portion 60 (link) formed between insulating sheaths 50 of adjacent wires 20. The linking portion 60 is formed as a single body with the insulating sheaths 50, and links adjacent wires 20 into a single body. The plurality of wires 20 are arranged side-by-side in the width direction of the vehicle (the left-right direction in FIG. 2(a)), for example.

The core wires 30 are elongated. The core wires 30 are flexible, and therefore are bendable into a shape extending along the route where the wire harness 10 is routed, for example. A twisted wire obtained by twisting a plurality of bare metal wires together, a columnar conductor (a single core wire, a bus bar, or the like) constituted by one columnar metal rod whose inside is solid, or a tubular conductor (a pipe conductor) whose inside is hollow can be used for the core wire 30, for example. A metallic material such as a copper-based material or an aluminum-based material can be used as the material of the core wire 30, for example. The core wires 30 are formed through extrusion molding, for example.

The transverse cross-sectional shape (i.e., a cross-sectional shape obtained by cutting a core wire 30 along a plane orthogonal to the length direction of the core wire 30) of each core wire 30 may be any shape and have any size. The transverse cross-sectional shape of each core wire 30 in this embodiment is a circular shape.

The electromagnetic shielding members 40 have a tubular shape, and respectively enclose the entire outer circumferences of the core wires 30. However, the electromagnetic shielding members 40 are provided at positions spaced apart from the outer circumferential surfaces of the core wires 30. In other words, the electromagnetic shielding members 40 respectively enclose the entire outer circumferences of the core wires 30 in a state in which the electromagnetic shielding members 40 are not in contact with the outer circumferential surfaces of the core wires 30.

The electromagnetic shielding members 40 have a shape extending along the outer circumferential surfaces of the respective core wires 30, for example. Each electromagnetic shielding member 40 in this embodiment has a cylindrical shape. The electromagnetic shielding members 40 are provided over substantially the entire length of the core wires 30 in their length direction, for example.

It is possible to use a braided member in which a plurality of bare metal wires are braided into a tubular shape, or a metal film for the electromagnetic shielding members 40, for example. The electromagnetic shielding members 40 of this embodiment are braided members. The electromagnetic shielding members 40 are more flexible than the core wires 30, for example.

Each insulating sheath 50 includes a covering portion 51 (first covering) formed between a core wire 30 and an electromagnetic shielding member 40, and a covering portion 52 (second covering) covering the outer circumference of the electromagnetic shielding member 40. The covering portion 51 and the covering portion 52 are formed as a single body in the insulating sheath 50, for example. The plurality of insulating sheaths 50 are formed as a single body via the linking portion 60. The insulating sheaths 50 are made of an insulating material such as synthetic resin, for example. It is possible to use polypropylene, polyamide, or the like as the synthetic resin, for example. It is possible to use, as the material of the insulating sheaths 50, curable resin such as photocurable resin or thermosetting resin, or curable resin in which multiple types of resins that are curable using different curing methods are mixed, for example. The insulating sheaths 50 can be formed by performing, for example, extrusion molding (extrusion coating) on the core wires 30 and the electromagnetic shielding members 40. The covering portion 51 and the covering portion 52 are formed through extrusion molding performed in the same step simultaneously, for example.

The covering portions 51 respectively cover the entire outer circumferential surfaces of the core wires 30 in intimate contact (by areal contact) therewith. The covering portions 51 respectively cover the entire inner circumferential surfaces of the electromagnetic shielding members 40 in intimate contact therewith. The covering portions 51 are formed such that a space between the outer circumferential surfaces of the core wires 30 and the inner circumferential surfaces of the electromagnetic shielding members 40 is filled with the covering portions 51. That is, each covering portion 51 is formed such that a space located inward of the inner circumferential surface of the respective electromagnetic shielding member 40 is filled with the covering portion 51. Thus, the transverse cross-sectional shape of the covering portion 51 of this embodiment is a round columnar shape. Note that the plurality of core wires 30 are respectively embedded in the covering portions 51.

The covering portions 52 respectively cover the entire outer circumferential surfaces of the electromagnetic shielding members 40 in intimate contact therewith. Accordingly, the outer circumferential surface of each electromagnetic shielding member 40 is covered by the covering portion 52, and the inner circumferential surface of each electromagnetic shielding member 40 is covered by the covering portion 51. In other words, the electromagnetic shielding members 40 are respectively embedded in the insulating sheaths 50 (the covering portions 51 and 52).

The insulating sheaths 50 (the covering portions 51 and 52) are formed to enter the mesh of the electromagnetic shielding members 40 (braided members), for example. The insulating sheaths 50 are formed such that the mesh of the electromagnetic shielding members 40 is filled with the insulating sheaths 50, for example.

The outer circumferential cross-sectional shape of the covering portions 52 may be any shape and have any size. The covering portions 52 have a shape extending along the outer circumferential surfaces of the respective core wires 30 and the respective electromagnetic shielding members 40, for example. The covering portions 52 in this embodiment have a substantially round columnar shape. However, a covering portion 52 of this embodiment is linked to the adjacent covering portion 52 due to a portion in the circumferential direction of the round column thereof being linked thereto via the linking portion 60. That is to say, with the plurality of wires 20 of this embodiment, an arc portion (curved surface) of the covering portion 52 of one of the wires 20 and an arc portion (curved portion) of the covering portion 52 of the other wire 20 are continuous with each other.

In this embodiment, the insulating sheaths 50 function as protective tubes in the wire harness 10 as a result of using a photocurable resin or a thermosetting resin as the material of the insulating sheaths 50. The insulating sheaths 50 made of a photocurable resin are formed through extrusion molding or the like, and the insulating sheaths 50 are irradiated with light (ultraviolet rays or the like), and thus the hardness of the insulating sheaths 50 can be increased, for example. Thus, the insulating sheaths 50 with increased hardness can function as protective tubes for protecting the core wires 30 from flying objects and water droplets. Note that, if a thermosetting resin is used as the material of the insulating sheaths 50, the heat-cured insulating sheaths 50 can also function as protective tubes in a similar manner.

If a photocurable resin or a thermosetting resin is used as the material of the insulating sheaths 50, the wires 20 are bent to follow a wiring route shown in FIG. 1, and the insulating sheaths 50 are cured through photocuring, heat-curing, or the like. The route where the wires 20 are routed can be maintained through this curing. That is, the insulating sheaths 50 in this case function as route-maintaining members for maintaining the route where the wires 20 are routed.

The linking portion 60 is formed as a single body with the covering portions 52. In other words, a portion of the plurality of covering portions 52 functions as the linking portion 60. The linking portion 60 extends in the length direction of the wires 20 (a direction orthogonal to the paper plane in FIG. 2(a)), for example. The linking portion 60 extends linearly in the thickness direction (the up-down direction in FIG. 2(a)) that is orthogonal to the length direction of the wires 20 and the direction in which the plurality of wires 20 are arranged in parallel to each other (in the left-right direction in FIG. 2(a)).

The linking portion 60 is formed between adjacent electromagnetic shielding members 40. The linking portion 60 is formed at a position spaced apart from the electromagnetic shielding members 40. The covering portions 52 of the insulating sheaths 50 are interposed between the linking portion 60 and the electromagnetic shielding members 40, respectively. In this embodiment, the thickness of a covering portion 52 interposed between the linking portion 60 and an electromagnetic shielding member 40 (i.e., a portion of the covering portion 52 connected to the linking portion 60) is smaller than the thickness of the other portion of the covering portion 52.

The linking portion 60 of this embodiment is provided at a position where arc portions (curved surfaces) of the covering portions 52 of the plurality of wires 20 overlap each other. Thus, the linking portion 60 is formed between the arc portion (curved surface) of the covering portion 52 of one of the wires 20 and the arc portion (curved surface) of the covering portion 52 of the other wire 20. Note that the size in the thickness direction of the linking portion 60 in this embodiment is set smaller than the size of the wires 20 in the thickness direction at a position passing through the center of the core wire 30.

As shown in FIG. 2(b), a plurality of groove portions 61 are formed in necessary portions of the linking portion 60. The groove portions 61 are recessed in the thickness direction (the up-down direction in FIG. 2(b)), for example. That is to say, each groove portion 61 is formed such that the size thereof in the thickness direction of the linking portion 60 is small. The wires 20 of this embodiment are provided with the groove portions 61 on both sides in the thickness direction. The transverse cross-sectional shape of each groove portion 61 may be any shape and have any size. The transverse cross-sectional shape of each groove portion 61 in this embodiment is V-shaped.

As shown in FIG. 3, the plurality of groove portions 61 are provided at predetermined intervals in the length direction of the wires 20. The gaps between the plurality of groove portions 61 may be formed at certain intervals or at different intervals. The groove portions 61 extend in the length direction of the wires 20, for example. A cutting line 62 is constituted by these groove portions 61. That is, the linking portion 60 of this embodiment is provided with the cutting line 62 constituted by the plurality of groove portions 61. The plurality of wires 20 are configured to be dividable at the linking portion 60 by using the cutting line 62. That is to say, the plurality of wires 20 can be divided into individual wires 20 by splitting the linking portion 60 along the plurality of groove portions 61 (the cutting line 62).

The plurality of wires 20 are divided into individual wires 20 along the linking portion 60 (the cutting line 62) at an end portion thereof in the length direction, for example. The end portions of the wires 20 of this embodiment are connected to the connectors C1 in a state in which the end portions are divided into individual end portions. That is to say, in this embodiment, the plurality of wires 20 are respectively connected to different connectors C1 in a divided state.

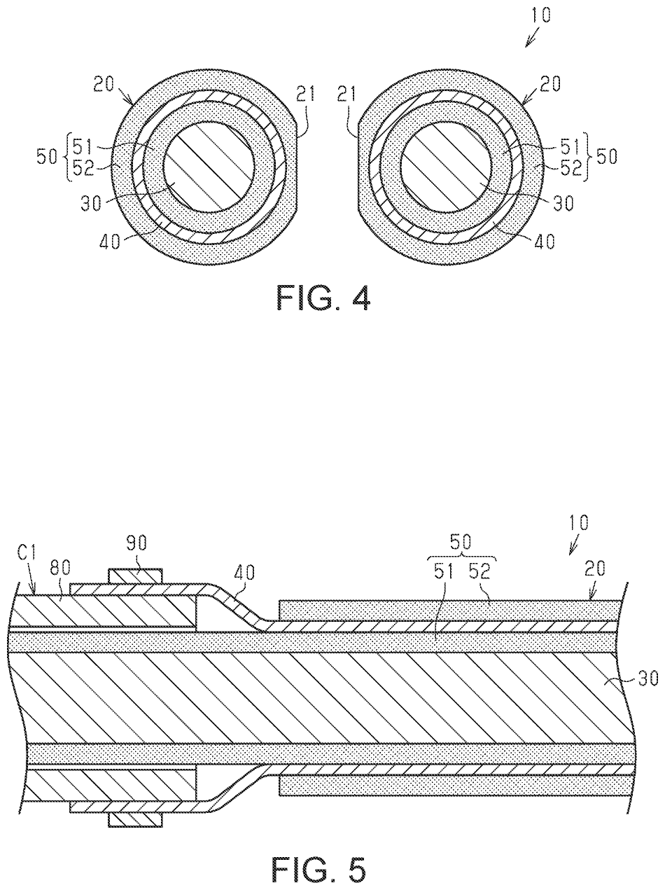

As shown in FIG. 4, the transverse cross-sectional shape of individually divided wires 20 (i.e., the wires 20 after division) is a non-circular shape, for example. A portion in the circumferential direction of the outer circumferential surface of each wire 20 after division has a flat surface portion 21. That is to say, a portion in the circumferential direction of the outer circumferential surface of the covering portion 52 (the insulating sheath 50) in each wire 20 after division has a flat surface portion 21. Thus, in the wire 20 after division, the outer circumferential cross-sectional shape of the covering portion 51 and the outer circumferential cross-sectional shape of the covering portion 52 are different shapes.

Next, the structure of end portions of the divided wires 20 will be described below with reference to FIG. 5. Here, the structure of an end portion of the wire 20 at the inverter 11 (see FIG. 1) will be described.

End portions of the divided wires 20 are inserted into conductive tubular members 80 of the connectors C1 connected to the inverter 11 (see FIG. 1). The divided wires 20 are inserted respectively into the tubular members 80, for example. That is, the connector C1 has a plurality (two in this embodiment) of tubular members 80. It is possible to use a metallic material such as an iron-based material or an aluminum-based material as the material of the tubular members 80, for example. The tubular members 80 may also be subjected to surface treatment such as tin plating or aluminum plating, in accordance with the types of constituent metals and usage environments. The tubular members 80 have a cylindrical shape, for example.

At an end portion of each wire 20, the covering portion 52 of the insulating sheath 50 covering the outer circumferential surface of the electromagnetic shielding member 40 is removed, and the electromagnetic shielding member 40 is exposed from the insulating sheath 50. Also, the end portion of the wire 20 is inserted into the inner portion of the tubular member 80 in a state in which the core wire 30 is covered by the covering portion 51 of the insulating sheath 50. That is to say, only the core wire 30 and the covering portion 51 of the wire 20 are inserted into the inner portion of the tubular member 80. Note that the covering portion 52 can be removed by selectively removing a resin portion (the covering portion 52) using a laser or the like, for example. At this time, the insulating sheath 50 with which the mesh of the electromagnetic shielding member 40 is filled may be removed, or left.

An end portion of the electromagnetic shielding member 40 exposed from the insulating sheath 50 is drawn out to be spaced apart from the covering portion 51 (the insulating sheath 50) covering the outer circumference of the core wire 30. The end portion of the electromagnetic shielding member 40 is fixed to the outer circumferential surface of the tubular member 80. The end portion of the electromagnetic shielding member 40 is fitted to the outside of the tubular member 80, enclosing the entire circumference of the tubular member 80, for example. The electromagnetic shielding member 40 is fitted to the outside of the tubular member 80 to be in direct contact with the outer circumferential surface of the tubular member 80.

The end portion of the electromagnetic shielding member 40 is connected to the outer circumferential surface of the tubular member 80 by a crimping ring 90 provided on the outer circumferential side of the electromagnetic shielding member 40. The crimping ring 90 is fitted to the outside of the tubular member 80 in a state in which the end portion of the electromagnetic shielding member 40 is held between the outer circumferential surface of the tubular member 80 and the crimping ring 90. Also, when the crimping ring 90 is crimped, the end portion of the electromagnetic shielding member 40 is tightly fixed to the outer circumferential surface of the tubular member 80 in a state in which the end portion of the electromagnetic shielding member 40 is in direct contact with the outer circumferential surface of the tubular member 80. This ensures a stable electrical connection between the electromagnetic shielding member 40 and the tubular member 80.

Although the structure of end portions of the wires 20 at the inverter 11 (see FIG. 1) has been described above, the same structure is provided to their end portions at the high-voltage battery 12 (see FIG. 1).

As shown in FIG. 3, the clamps 70 are attached to the outer circumferential surfaces of the insulating sheaths 50 of the wires 20, for example. The clamps 70 are fixed to a vehicle body by fixing portions (not shown). The plurality of wires 20 are fixed to the vehicle body by the clamps 70. A resin material or a metallic material can be used as the material of the clamps 70, for example. It is possible to use a conductive resin material or a resin material that has no conductivity as the resin material, for example. It is possible to use a metallic material such as an iron-based material or an aluminum-based material as the metallic material, for example.

Next, effects of this embodiment will be described below.

(1) The insulating sheath 50 is provided which has the covering portion 51 that is filled between a core wire 30 and a tubular electromagnetic shielding member 40 enclosing an outer circumference of the core wire 30, and the covering portion 52 that covers an outer circumferential surface of the electromagnetic shielding member 40 in intimate contact therewith. According to this configuration, because the covering portion 51 is filled between the core wire 30 and the electromagnetic shielding member 40, it is possible to inhibit an air layer, which is a heat insulating layer, from being interposed between the outer circumferential surface of the core wire 30 and the inner circumferential surface of the electromagnetic shielding member 40. Accordingly, the thermal resistance between the outer circumferential surface of the core wire 30 and the inner circumferential surface of the electromagnetic shielding member 40 can be reduced. Also, because the covering portion 52 covers the outer circumferential surface of the electromagnetic shielding member 40 in intimate contact therewith, it is possible to inhibit an air layer, which is a heat insulating layer, from being interposed between the electromagnetic shielding member 40 and the covering portion 52. Accordingly, the thermal resistance between the outer circumferential surface of the electromagnetic shielding member 40 and the inner circumferential surface of the covering portion 52 can be reduced. This inhibits heat generated by the core wire 30 from being trapped in the insulating sheath 50, and allows heat generated by the core wire 30 to be efficiently released from the outer circumferential surface of the insulating sheath 50 to the atmosphere. This makes it possible to efficiently release heat generated by the core wire 30 and to improve the heat dissipation properties of the wire harness 10. As a result, it is possible to keep the temperature of the wire 20 from increasing.

(2) The insulating sheath 50 is formed to collectively cover the plurality of core wires 30. Thus, it is possible to further reduce a gap between adjacent core wires 30, and to further reduce the size of the wire 20, compared to a case where a plurality of wires in which core wires are respectively covered by insulating sheaths are arranged side-by-side.

(3) The groove portions 61 are formed in the linking portion 60 so that the plurality of wires 20 are dividable into individual wires at the linking portion 60. Due to the groove portions 61 being formed, the plurality of wires 20 can be divided into individual wires 20 by splitting the linking portion 60 along the groove portions 61. Accordingly, the plurality of wires 20 formed as a single body can be divided into individual wires 20 at the end portion thereof, and be connected to a connector C1 in the divided state, for example. In this case, the plurality of wires 20 can be individually connected to the connector C1 even if the plurality of wires 20 are formed as a single body, and thus it is possible to suppress deterioration in the operability for connecting the wires 20 and the connector C1.

(4) The linking portion 60 is provided with a plurality of groove portions 61 at predetermined intervals in the length direction of the wires 20. According to this configuration, when the plurality of wires 20 are divided into individual wires 20 by splitting the plurality of wires 20 along the groove portions 61, this dividing operation can be easily stopped at the linking portion 60 where no groove portions 61 are formed. Accordingly, the length by which the plurality of wires 20 are divided can be easily adjusted.

(5) The thickness of a portion of the covering portion 52 connected to the linking portion 60 is smaller than the thickness of the other portion of the covering portion 52. Accordingly, the plurality of wires 20 can be easily divided because the wires 20 can be easily split along the linking portion 60.

(6) A photocurable resin or a thermosetting resin is used as the material of the insulating sheath 50. This insulating sheath 50 functions as a protective tube in the wire harness 10. The insulating sheath 50 made of a photocurable resin is formed through extrusion molding or the like, and the insulating sheath 50 is irradiated with light (ultraviolet rays or the like), and thereby the hardness of the insulating sheath 50 can be increased, for example. Thus, the insulating sheath 50 with increased hardness can function as a protective tube for protecting the core wires 30 from flying objects and water droplets. Note that, if a thermosetting resin is used as the material of the insulating sheath 50, the heat-cured insulating sheath 50 can also function as a protective tube in a similar manner. As a result, it is possible to omit a protective tube, and to reduce the number of components. Furthermore, because the outer circumferential surface of the insulating sheath 50 serves as the outer surface of the wire harness 10, heat generated by the core wires 30 can be efficiently released from the outer circumferential surface of the insulating sheath 50 to the atmosphere.

(7) Also, after the wires 20 have been bent to follow a desired wiring route, the insulating sheath 50 can be cured through photocuring, heat-curing, or the like. Thus, because bending is performed on the wires 20 with greater flexibility than that once the insulating sheath 50 has been cured, the wires 20 can be bent with ease. On the other hand, the rigidity of the insulating sheath 50 can be increased through photocuring, heat-curing, or the like, and thus, the route where the wires 20 are routed can be maintained by the insulating sheath 50.

(8) The clamps 70 are attached to the outer circumferential surface of the insulating sheath 50 and fix the insulating sheath 50 to a vehicle body. According to this configuration, it is possible to efficiently transfer heat generated by the core wires 30 to the vehicle body with a large surface area through the insulating sheath 50 and the clamps 70. This makes it possible to efficiently release heat generated by the core wires 30 and to improve the heat dissipation properties of the wire harness 10.

(9) At end portions of the wires 20, the end portions of the electromagnetic shielding members 40 are exposed from the covering portions 52, and the exposed end portions of the electromagnetic shielding members 40 are connected to the outer circumferential surfaces of the tubular members 80 by the crimping rings 90. According to this configuration, even if the electromagnetic shielding members 40 are embedded in the inner portions of the insulating sheaths 50, a stable electrical connection between the electromagnetic shielding members 40 and the tubular members 80 can be ensured by removing the covering portions 52 at the end portions of the electromagnetic shielding members 40.

### Other Embodiments

The above-described embodiment can be modified as follows. The embodiment described above and following modifications may be combined to the extent that they do not contradict each other technically.
The covering portions 51 and the covering portions 52 in the above-described embodiment need only be layered with the electromagnetic shielding member 40 held therebetween, and need not be formed simultaneously in the same step. The covering portions 51 for covering the outer circumference of each core wire 30 may be formed through extrusion molding, the electromagnetic shielding member 40 may be stacked on the outer circumferential surface of the corresponding covering portion 51, and then the covering portions 52 for covering the outer circumference of the electromagnetic shielding members 40 may be formed through extrusion molding, for example.
The covering portions 51 and the covering portions 52 in the above-described embodiment may be made of different resin materials. The covering portions 52 may be made of a curable resin such as a photocurable resin, and the covering portions 51 may be made of a resin material that is cheaper than the curable resin, for example. Even with such a configuration, the effects (6) and (7) of the above-described embodiment can be achieved because the covering portions 52 are made of a curable resin. Furthermore, a reduction in costs can be realized due to the covering portions 51 being made of an inexpensive resin material.
Although the transverse cross-sectional shape of each groove portion 61 is V-shaped in the above-described embodiment, there is no particular limitation thereto. The transverse cross-sectional shape of the groove portion 61 may be U-shaped or I-shaped, for example.
The plurality of groove portions 61 are formed in the linking portion 60 at predetermined intervals in the length direction of the wires 20 in the above-described embodiment. There is no limitation thereto, and a groove portion that extends over the entire length of the wires 20 in the length direction may be formed in the linking portion 60, for example.
The groove portions 61 are formed on both sides of the linking portion 60 in the thickness direction in the above-described embodiment. There is no limitation thereto, and the groove portions 61 may be formed only on one side of the linking portion 60 in the thickness direction.
Although the plurality of wires 20 are configured to be dividable at the linking portion 60 due to the linking portion 60 being provided with the groove portions 61 in the above-described embodiment, there is no limitation thereto.

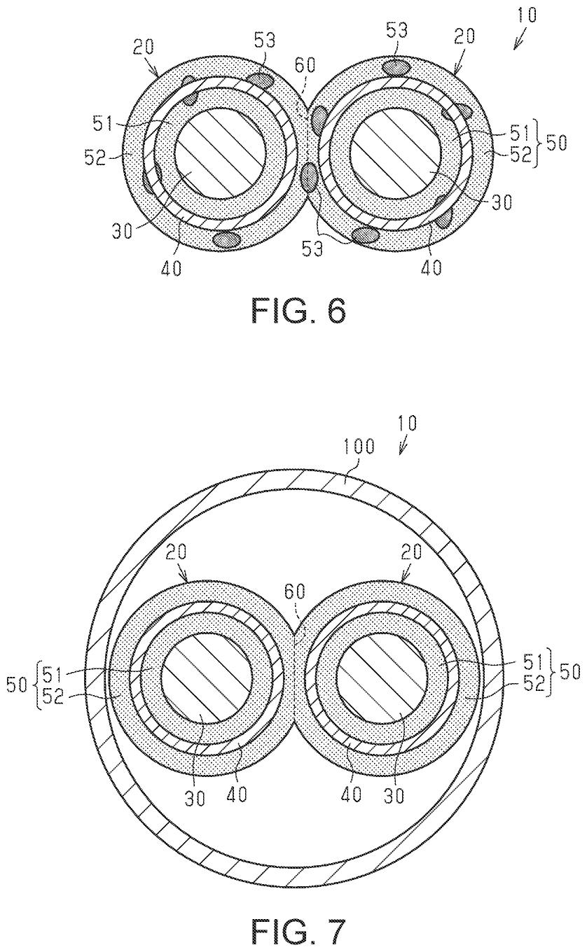

As shown in FIG. 6, the inner portion of the linking portion 60 may contain a resin 53 that is different from the resin constituting the insulating sheath 50, for example. The insulating sheath 50 also contains the resin 53, for example. The resin 53 may be provided scattered in the linking portion 60 and the inner portion of the insulating sheath 50, or may be provided only in the linking portion 60 and the inner portion of the insulating sheath 50 located in the vicinity of the linking portion 60. A resin with poor adhesion to the resin constituting the insulating sheath 50 can be used as the resin 53, for example. According to this configuration, the plurality of wires 20 can be easily split along the linking portion 60 because of the increased vulnerability at the linking portion 60. Accordingly, the plurality of wires 20 can be divided into individual wires 20 at the linking portion 60. In this case, the formation of the groove portions 61 can be omitted.
Although the insulating sheath 50 is photocured or heat-cured over substantially the entire length in the above-described embodiment, the insulating sheath 50 may be partially photocured or heat-cured. According to this configuration, the shape of the insulating sheath 50 (the wires 20) can be partially fixed.
Although the outer circumferential surface of the insulating sheath 50 of the wires 20 is configured to be the outer surface of the wire harness 10 in the above-described embodiment, there is no limitation thereto.

As shown in FIG. 7, a configuration may be adopted in which a protective tube 100 for enclosing the outer circumferences of the insulating sheath 50 of the wires 20 is provided, for example. The protective tube 100 has an overall elongated tubular shape. The wires 20 are inserted into the inner portion of the protective tube 100. Metal pipes or resin pipes, corrugated tubes, waterproof rubber covers, or a combination thereof may be used for the protective tube 100, for example. A metallic material such as an aluminum-based material or a copper-based material can be used as the material of a metal pipe or a corrugated tube, for example. A conductive resin material or a resin material that has no conductivity can be used as the material of a resin pipe or a corrugated tube, for example. It is possible to use synthetic resin such as polyolefin, polyamide, polyester, or an ABS resin, for this resin material, for example.

At this time, with the wires 20, the outer circumferential surface of the electromagnetic shielding member 40 is covered by the covering portion 52 of the insulating sheath 50 in intimate contact therewith, and thus radiant heat from the electromagnetic shielding member 40 is blocked by the covering portion 52. That is to say, the covering portion 52 in this modification functions as a blocking member for blocking radiant heat from the electromagnetic shielding member 40. Thus, radiant heat from the electromagnetic shielding member 40 can be kept from being transferred to the protective tube 100. This can inhibit heat from being trapped in the protective tube 100.

Note that a clamp for fixing the protective tube 100 to the vehicle body is attached to the outer circumferential surface of the protective tube 100 in this modification.
The plurality of wires 20 are divided at the end portions thereof, and the divided wires 20 are respectively connected to different connectors C1 in the above-described embodiment. However, there are no particular limitations on a state in which the wires 20 and the connectors C1 are connected to each other and the route where the wire harness 10 is routed.

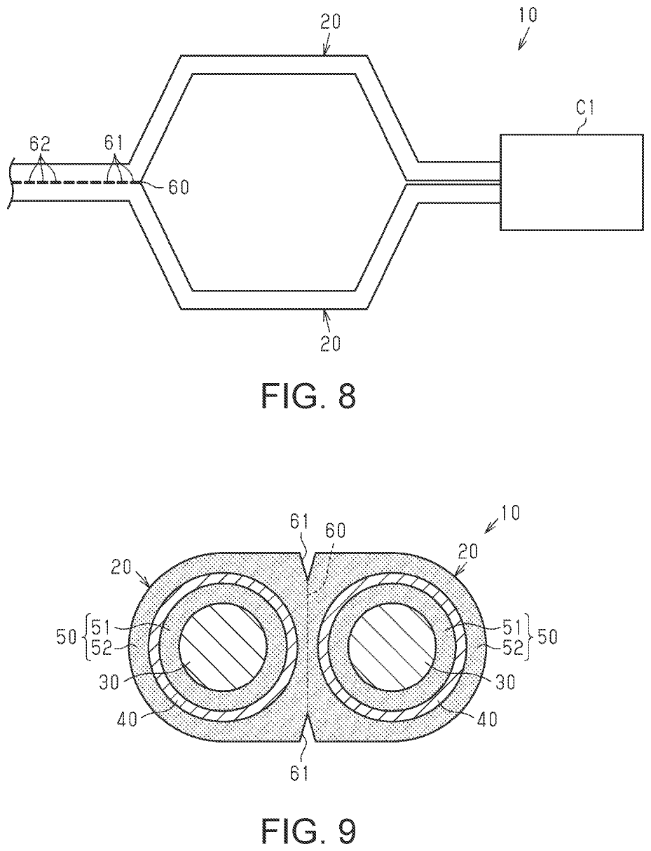

As shown in FIG. 8, the plurality of wires 20 may be divided to be separated from each other, and then the separated wires 20 may be brought close and connected to one connector C1, for example. At this time, the end portions of the plurality of wires 20 connected to the connector C1 are arranged at positions at which the end portions are close to each other, and these end portions are connected to one connector C1 in a divided state. Because the plurality of wires 20 are configured to be dividable at the linking portion 60 in this manner, the degree of freedom of the layout of the wire harness 10 can be increased.
Although the outer circumference of the covering portion 52 has a shape extending along the outer circumferences of the core wire 30 and the electromagnetic shielding member 40 in the above-described embodiment, there is no limitation thereto.

As shown in FIG. 9, the transverse cross-sectional shape of the insulating sheath 50 may be a flat shape for collectively covering the plurality of core wires 30 and the electromagnetic shielding members 40 that are arranged side-by-side, for example. The covering portion 52 may have a flat outer circumferential cross-sectional shape, for example. In this specification, “flat shape” includes rectangular, oval, and elliptical shapes, for example. The covering portion 52 in this modification has an oval outer circumferential cross-sectional shape. Here, “oval shape” in this specification is a shape constituted by two parallel lines with substantially equal lengths and two semicircles.

With this configuration, the size of the linking portion 60 in the thickness direction is larger than that of the linking portion 60 shown in FIG. 2. Specifically, the size of the linking portion 60 of this modification in the thickness direction is substantially the same as the size of each wire 20 in the thickness direction at a position passing through the center of the core wire 30. Thus, it is preferable to provide the groove portions 61 in the linking portion 60 in this modification.
Although the crimping ring 90 is used as a linking member for fixing the electromagnetic shielding member 40 to the outer circumferential surface of the tubular member 80 in the above-described embodiment, there is no limitation thereto. A metal band, or a cable tie or adhesive tape made of resin, or the like may also be used as a linking member, instead of the crimping ring 90, for example.
The transverse cross-sectional shape of the core wire 30 in the above-described embodiment may be an oval, elliptical, rectangular, square, or semicircular shape.
Although two wires 20 are formed as a single body in the above-described embodiment, there is no limitation thereto. The number of wires 20 can be changed in accordance with the specifications of a vehicle. The number of wires 20 formed as a single body may be three or more, for example. Low-voltage electrical wires that connect a low-voltage battery and various low-voltage devices (e.g., a lamp and a car audio device) may be added as wires constituting the wire harness 10, for example.
The arrangement relationship between the inverter 11 and the high-voltage battery 12 in the vehicle is not limited to that in the above-described embodiment, and may be changed as appropriate in accordance with the configuration of the vehicle.
Although the inverter 11 and the high-voltage battery 12 are adopted as the electric apparatuses connected by the wires 20 in the above-described embodiment, there is no limitation to this. The present disclosure is also applicable to wires that connect the inverter 11 and a wheel driving motor, for example. That is, it can be applied to any component that electrically connects electric apparatuses installed in a vehicle.

The present disclosure encompasses the following implementation examples. Not for limitation but for assistance in understanding, the reference numerals of the representative components in the representative embodiment are provided.

[Appendix 1] In one or more implementation examples of this disclosure, the wire harness (10) may include a plurality of conductive core wires (30), a plurality of tubular electromagnetic shielding members (40) that respectively enclose the plurality of conductive core wires (30), a plurality of inner insulating resin layers (51) for electrically insulating the plurality of conductive core wires (30) and the plurality of tubular electromagnetic shielding members (40), and a plurality of outer insulating resin layers (52) that respectively enclose the tubular electromagnetic shielding members (40) from the outside and are respectively in intimate contact with outer circumferential surfaces of the tubular electromagnetic shielding members (40),

in which an outer circumferential surface of each conductive core wire (30) may be separated by a gap from an inner circumferential surface of the corresponding tubular electromagnetic shielding member (40) over the entire length or substantially the entire length of the plurality of conductive core wires (30),

an empty space between the outer circumferential surfaces of the plurality of conductive core wires (30) and the inner circumferential surfaces of the plurality of tubular electromagnetic shielding members (40) may be filled with or occupied by the plurality of inner insulating resin layers (51) over the entire length or substantially the entire length of the plurality of conductive core wires (30),

the plurality of outer insulating resin layers (52) may be formed as a single body by insulating resins having the same composition, and the plurality of outer insulating resin layers (52) may be linked together by a linking portion (60) made of the insulating resin, and

the plurality of outer insulating resin layers (52) may include a strength weakening portion (61 and 62; 53) for locally weakening strength at the linking portion (60) such that the plurality of outer insulating resin layers (52) are separable from each other in a range of a desired length in a length direction of the plurality of conductive core wires (30).

[Appendix 2] In one or more implementation examples of this disclosure, the strength weakening portion (61, 62) may be a row of holes, or perforations (61, 62) that are formed in the length direction of the plurality of conductive core wires (30).

[Appendix 3] In one or more implementation examples of this disclosure, outer circumferential surfaces of two adjacent outer insulating resin layers (52) may form a wedge-shaped constriction extending over the entire length of the outer insulating resin layers (52) at a boundary between the two adjacent insulating resin layers (52), and

the strength weakening portion (61, 62) may be a row of holes, or perforations (61, 62) that are formed in the length direction of the plurality of conductive core wires (30) in the wedge-shaped constriction.

[Appendix 4] In one or more implementation examples of this disclosure, outer circumferential surfaces of two adjacent outer insulating resin layers (52) may form a wedge-shaped constriction extending over the entire length of the outer insulating resin layers (52) at a boundary between the two adjacent insulating resin layers (52), and

the strength weakening portion (53) may contain synthetic resin particles (53) that are dispersed throughout the outer insulating resin layers (52) or are locally dispersed in the linking portion (60), and that facilitate splitting of the two adjacent outer insulating resin layers (52) at the wedge-shaped constriction.

[Appendix 5] In one or more implementation examples of this disclosure, the plurality of inner insulating resin layers (51) are in intimate contact with the outer circumferential surfaces of the plurality of conductive core wires (30) and the inner circumferential surfaces of the plurality of tubular electromagnetic shielding members (40) over the entire length or substantially the entire length of the plurality of conductive core wires (30).

[Appendix 6] In one or more implementation examples of this disclosure, each inner insulating resin layer (51) may be longer than the corresponding tubular electromagnetic shielding member (40).

[Appendix 7] In one or more implementation examples of this disclosure, the inner insulating resin layers (51) may continuously extend over the entire length or substantially the entire length of the plurality of conductive core wires (30).

[Appendix 8] In one or more implementation examples of this disclosure, no air path that continuously extends over the entire length or substantially the entire length of the plurality of conductive core wires (30) is formed between the outer circumferential surfaces of the plurality of conductive core wires (30) and the inner circumferential surfaces of the plurality of inner insulating resin layers (51).

[Appendix 9] In one or more implementation examples of this disclosure, no air path that continuously extends over the entire length or substantially the entire length of the plurality of conductive core wires (30) is formed between the outer circumferential surfaces of the inner insulating resin layers (51) and the inner circumferential surfaces of the plurality of tubular electromagnetic shielding members (40).

[Appendix 10] In one or more implementation examples of this disclosure, each outer insulating resin layer (52) may be shorter than the corresponding tubular electromagnetic shielding member (40).

[Appendix 11] In one or more implementation examples of this disclosure, an insulating resin forming the plurality of inner insulating resin layers (51) and an insulating resin forming the plurality of outer insulating resin layers (52) may have the same composition.

[Appendix 12] In one or more implementation examples of this disclosure, the plurality of inner insulating resin layers (51) and/or the plurality of outer insulating resin layers (52) may be made of a curable resin.

[Appendix 13] A wire harness (10) according to one or more implementation examples of this disclosure may have one or more bent portions, in which the plurality of inner insulating resin layers (51) and/or the plurality of outer insulating resin layers (52) that correspond at the one or more bent portions may be cured such that the one or more bent portions maintain a bent shape that conforms to a route where the wire harness (10) is routed.

[Appendix 14] In one or more implementation examples of this disclosure, the wire harness (10) may be routed in a wiring route that includes a straight portion and a bent portion, and be configured to electrically connect a plurality of electrical devices (11 and 12), in which the plurality of inner insulating resin layers (51) and the plurality of outer insulating resin layers (52) have bending rigidity that is set such that the plurality of conductive core wires (30) maintain a shape with a length that is matched to that of the wiring route.

[Appendix 15] In one or more implementation examples of this disclosure, the plurality of tubular electromagnetic shielding members (40) may be braided members, and an insulating resin forming the plurality of inner insulating resin layers (51) and/or an insulating resin forming the plurality of outer insulating resin layers (52) may enter the mesh of the braided members.

[Appendix 16] In one or more implementation examples of this disclosure, the plurality of outer circumferential surfaces of the plurality of outer insulating resin layers (52) may form an outer surface of the wire harness (10). [Appendix 17] In one or more implementation examples of this disclosure, the plurality of conductive core wires (30) may extend in parallel to each other without intersecting with each other.

[Appendix 18] In one or more implementation examples of this disclosure, the plurality of conductive core wires (30) may be a power supply line.

It will be apparent to those skilled in the art that the present disclosure may be embodied in other specific forms without departing from the technical concept of the present disclosure. Some of the components described in the embodiment (or one or more aspects thereof) may be omitted, or some of the components may be combined, for example. The scope of the present disclosure should be determined with reference to the appended claims, along with the full scope of equivalents to which such claims are entitled.

1. A wire harness comprising:
a plurality of wires each including
a core wire,
a tubular electromagnetic shield enclosing an outer circumference of the core wire, and
an insulating sheath that includes:
a first covering that is filled between the core wire and the electromagnetic shield, that covers an outer circumferential surface of the core wire in intimate contact therewith, and that covers an inner circumferential surface of the electromagnetic shield in intimate contact therewith, and
a second covering that covers an outer circumferential surface of the electromagnetic shield in intimate contact therewith; and
a link that is formed as a single body with the second covering in each of the plurality of wires, and that is for linking adjacent wires of the plurality of wires into a single body;
wherein the plurality of wires are configured to be dividable at the link.

2. The wire harness according to claim 1,
wherein a groove is formed in the link.

3. The wire harness according to claim 2,
wherein the groove includes a plurality of grooves that are provided at predetermined intervals in a length direction of the plurality of wires.

4. The wire harness according to claim 1,
wherein a thickness of a portion of the second covering connected to the link is smaller than a thickness of another portion of the second covering.

5. The wire harness according to claim 1,
wherein the link contains resin that is different from that of the insulating sheath.

6. The wire harness according to claim 1,
wherein the plurality of wires are connected to a connector in a state in which the plurality of wires are divided into individual wires.

7. The wire harness according to claim 1,
wherein the second covering is made of a photocurable resin or a thermosetting resin.

8. The wire harness according to claim 7, further comprising
a clamp that is attached to an outer circumferential surface of the insulating sheath and that is for fixing the insulating sheath to a vehicle body.

9. The wire harness according to claim 1, further comprising
a tubular protective tube enclosing an outer circumference of the insulating sheath.

10. The wire harness according to claim 1, further comprising
a conductive tube having an outer circumferential surface to which an end of each of the electromagnetic shields is connected, wherein:
at an end of the core wire, an end of the electromagnetic shield is exposed from the second covering, and the end of the core wire is inserted into an inner portion of the tube in a state in which the end of the core wire is covered by the first covering, and
the end of the electromagnetic shield that is exposed from the second covering is connected to the outer circumferential surface of the tube by the link.
